(19) United States
(12) Patent Application Publication
(10) Pub. No.: US 2015/0370162 A1
(43) Pub. Date: Dec. 24, 2015

(54) PHOTOSENSITIVE RESIN COMPOSITION FOR BLACK MATRIX AND APPLICATION THEREOF

(71) Applicant: CHI MEI CORPORATION, Tainan City (TW)

(72) Inventors: Hung-Chia CHOU, KAOHSIUNG CITY (TW); Hao-Wei LIAO, KAOHSIUNG CITY (TW)

(21) Appl. No.: 14/729,052

(22) Filed: Jun. 2, 2015

(30) Foreign Application Priority Data
Jun. 23, 2014 (TW) 103121532

(51) Int. Cl. G03F 7/004; G02B 5/20

(52) U.S. Cl. CPC G03F 7/004; G02B 5/20

(57) ABSTRACT

The present invention relates to a photosensitive resin composition for black matrix and an application thereof. The aforementioned photosensitive resin composition includes an alkali-soluble resin (A), a compound having an unsaturated vinyl group (B), a photo-initiator (C), a solvent (D), a black pigment (E) and a fluorescent brightening agent (F). The aforementioned alkali-soluble resin (A) includes a resin having an unsaturated group (A-1), and the resin having the unsaturated group (A-1) is obtained by polymerizing a mixture, and the mixture comprises an epoxy compound having at least two epoxy groups (a-1-1) and a compound having at least one carboxylic group and at least one vinyl unsaturated group (a-1-2).

### RELATED APPLICATIONS

This application claims priority to Taiwan Patent Application Serial Number 103121532, filed on Jun. 23, 2014. The entirety of the above-mentioned application is hereby incorporated by reference and made a part of this specification.

### BACKGROUND

1. Field of Invention

The present invention relates to a photosensitive resin composition for black matrix and the application thereof. More particularly, the present invention is to provide a photosensitive resin composition for black matrix having a superior heat-enduring resistance stability, a color filter formed by using the composition, and a liquid crystal display including the color filter.

2. Description of Related Art

Recently, as various technologies of liquid crystal display are promptly developed, a black matrix is configured in the gaps between stripes and dots of the color filter in a liquid crystal display, for improving the contract ratio and display quality of the liquid crystal display. The black matrix can prevent the reduction of contrast ratio and the reduction of color purity due to the light leakage between pixels.

Generally, the black matrix may be a deposited film including chromium or chromium oxide. However, the black matrix formed by such deposited film causes several disadvantages such as the complicated process the expensive material. To solve this issue, the black matrix may be formed by photolithographic process.

Japan published patent application No. 2006-259716 discloses a photosensitive resin composition for black matrix. The photosensitive resin composition includes a high amount of a black pigment, an alkali-soluble resin, a photopolymerization initiator, a reactive monomer having two functional groups, and an organic solvent. The reactive monomer having two functional groups can improve the reaction among the compounds so as to form a fine pattern. Therefore, the resulted photosensitive resin composition has a good light-shielding property and high sensitivity.

Moreover, Japan published patent application No. 2008-268854 discloses a photosensitive resin composition for black matrix. The photosensitive resin composition an alkali-soluble resin having a carboxylic group and an unsaturated group, a photopolymerizable monomer having an ethylenically unsaturated group, a photopolymerization initiator, and a black pigment in high amount. The alkali-soluble resin having a carboxylic group and an unsaturated group may improve the resolution of the photosensitive resin composition.

Although the light-shielding property of the photosensitive resin composition may be enhanced by increasing the amount of the black pigment, the photosensitive resin composition still has a poor heat-enduring resistance stability, and the performance of the black matrix is consequently deteriorated.

Therefore, there is an urgent issue to be solved in this technical field about how to improve the heat-enduring resistance stability of the photosensitive resin composition to fulfil the demand of the industries.

### SUMMARY

Therefore, an aspect of the present invention is to provide a photosensitive resin composition for black matrix. The photosensitive resin composition increases the heat-enduring resistance stability of the black matrix.

Another aspect of the present invention is to provide a black matrix formed by pre-baking, exposuring, developing, and post-baking the above-mentioned photosensitive resin composition.

Another aspect of the present invention is to provide a color filter including the above-mentioned black matrix.

Another aspect of the present invention is to provide a liquid crystal display including the above-mentioned color filter.

According to the above-mentioned aspects of the present invention, a photosensitive resin composition for black matrix is provided, wherein the photosensitive resin composition includes an alkali-soluble resin (A), a compound having an ethylenically unsaturated group (B) compound having an ethylenically unsaturated group (B), a photoinitiator (C), a solvent (D), a black pigment (E), and a fluorescent brightening agent (F), which will be discussed below.

### Photosensitive Resin Composition

### Alkali-Soluble Resin (A)

The alkali-soluble resin (A) of the present invention can include a resin having an unsaturated group (A-1). Moreover, the alkali-soluble resin (A) can optionally include another alkali-soluble resin (A-2).

Resin Having an Unsaturated Group (A-1)

The resin having an unsaturated group (A-1) is obtained by polymerizing a mixture. The mixture includes an epoxy compound having at least two epoxy groups (a-1-1) and a compound having at least one carboxylic group and at least one ethylenically unsaturated group (a-1-2). Moreover, the mixture can optionally include a carboxylic acid anhydride compound (a-1-3) and a compound (a-1-4) having an epoxy group.

Epoxy Compound Having at Least Two Epoxy Groups (A-1-1)

The epoxy compound having at least two epoxy groups (a-1-1) includes the structure shown in formula (I) below, the structure shown in formula (II) below, or a combination of the two structures:

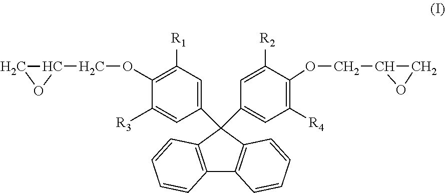

in the formula (I), R₁ to R₄ each independently represent a hydrogen atom, a halogen atom, a C₁-C₅ alkyl group, a C₁-C₅ alkoxy group, a C₆-C₁₂ aryl group, or a C₆-C₁₂ aralkyl group.

The compound having the structure represented by formula (I) can include a bisphenol fluorene-type compound having an epoxy group obtained by reacting a bisphenol fluorene and epihalohydrin.

Specifically, specific examples of the bisphenol fluorene-type compound can include 9,9-bis(4-hydroxyphenyl)fluorine, 9,9-bis(4-hydroxy-3-methylphenyl)fluorine, 9,9-bis(4-hydroxy-3-chlorophenyl)fluorine, 9,9-bis(4-hydroxy-3-bromophenyl)fluorine, 9,9-bis(4-hydroxy-3-fluorophenyl)fluorine, 9,9-bis(4-hydroxy-3-methoxyphenyl)fluorine, 9,9-bis(4-hydroxy-3,5-dimethylphenyl)fluorine, 9,9-bis(4-hydroxy-3,5-dichlorophenyl)fluorine, 9,9-bis(4-hydroxy-3,5-dibromophenyl)fluorine, or a similar compound thereof, or any combination of the above-mentioned compounds.

Specific examples of the epihalohydrin can include epichlorohydrin, epibromohydrin, or a similar compound thereof, or any combination of the above-mentioned compounds.

Specific examples of the bisphenol fluorene-type compound having an epoxy group include (1) products made by Nippon Steel Chemical Co., Ltd. such as the trade name of ESF-300 or similar products thereof; (2) products made by Osaka Gas Co., Ltd. such as the trade names of PG-100, EG-210, or similar products thereof; or (3) products made by S.M.S. Technology Co. such as the trade names of SMS-F9PhPG, SMS-F9CrG, SMS-F914PG, or similar products thereof.

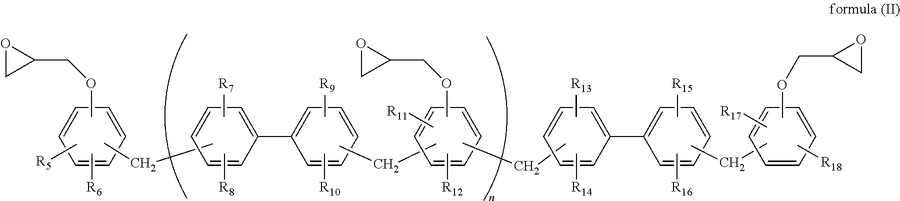

in the formula (II), R₅ to R₁₈ each independently represent a hydrogen atom, a halogen atom, a C₁-C₈ alkyl group, or a C₆-C₁₅ aryl group; n represents an integer of 0 to 10.

The compound having the structure represented by the formula (II) can be obtained by reacting a compound having the structure of the formula (II-1) and epihalohydrin under the existence of an alkali metal hydroxide.

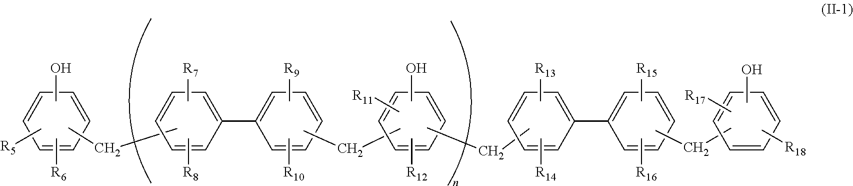

in the formula (II-1), the definition of each of R₅ to R₁₈ and n is the same as described above, and is not repeated herein.

The synthesis method of the compound having the structure represented by the formula (II) is as follows: firstly, a condensation reaction is conducted for a compound having the structure of formula (II-1-1) and a phenol under the existence of an acid catalyst to form a compound having the structure of formula (II-1):

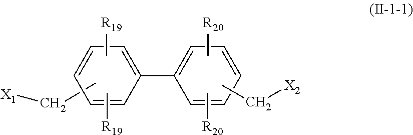

in the formula (II-1-1), R₁₉ and R₂₀ each independently represent a hydrogen atom, a halogen atom, a C₁-C₈ alkyl group, or a C₆-C₁₅ aryl group; X₁ and X₂ each independently represent a halogen atom, a C₁-C₆ alkyl group, or a C₁-C₆ alkoxy group. The alkyl group is preferably a methyl group, an ethyl group, or tertiary butyl. The alkoxy group is preferably a methoxy group or an ethoxy group.

Specific examples of the phenol include phenol, cresol, ethylphenol, n-propylphenol, isobutylphenol, t-butylphenol, octylphenol, nonylphenol, xylenol, methylbutylphenol, di-t-butylphenol, vinylphenol, propenylphenol, ethinylphenol, cyclopentylphenol, cyclohexylphenol, cyclohexylcresol, or a similar compound thereof. The phenol can be used alone or in any combination.

Based on a usage amount of 1 mole of the compound having the structure of the formula (II-1-1), the usage amount of phenol is 0.5 mole to 20 mole, and preferably 2 mole to 15 mole.

Specific examples of the acid catalyst include hydrochloric acid, sulfuric acid, p-toluenesulfonic acid, oxalic acid, boron trifluoride, aluminium chloride anhydrous, zinc chloride, or a similar compound thereof. The acid catalyst can be used alone or in any combination.

The acid catalyst is preferably p-toluenesulfonic acid, sulfuric acid, hydrochloric acid, or any combination of the above-mentioned compounds.

Moreover, the usage amount of the acid catalyst is not particularly limited. However, based on a usage amount of 100 parts by weight of the compound having the structure of the formula (II-1-1), the usage amount of the acid catalyst is preferably 0.1 parts by weight to 30 parts by weight.

The condensation reaction can be conducted without a solvent or under the existence of an organic solvent. Specific examples of the organic solvent include toluene, xylene, methyl isobutyl ketone, or a similar compound thereof. The organic solvent can be used alone or in any combination.

Based on a total weight of 100 parts by weight of the compound having the structure of the formula (II-1-1) and the phenol, the usage amount of the organic solvent is 50 parts by weight to 300 parts by weight and preferably 100 parts by weight to 250 parts by weight.

The reaction temperature of the condensation reaction is 40° C. to 180° C. and the reaction time of the condensation reaction is 1 hour to 8 hour.

After the condensation reaction is completed, a neutralization treatment or a rinse treatment can be optionally conducted.

In the neutralization treatment, the pH value of the reacted solution is adjusted to 3 to 7, and preferably 5 to 7.

The rinse treatment can be conducted by using a neutralizer, wherein the neutralizer is an alkaline substance, and specific examples thereof include ammonia, sodium dihydrogen phosphate; alkali metal hydroxides such as sodium hydroxide, potassium hydroxide, etc.; alkaline earth metal hydroxides such as calcium hydroxide, magnesium hydroxide, etc.; organic amines such as diethylene triamine, triethylenetetramine, aniline, phenylene diamine, etc.; or any combination of the above-mentioned compounds. The neutralizing agent can be used alone or in any combination.

The rinse treatment can be conducted with a known method, such as adding an aqueous solution containing a neutralizer in the reacted solution and then extracting repeatedly. After the neutralization treatment or the rinse treatment, the unreacted phenol and solvent can be distilled off through a heat treatment under reduced pressure, and then condensation is conducted to obtain the compound having the structure of the formula (II-1).

Then, an excessive amount of epihalohydrin is added to proceed dehydrohalogenation on the epihalohydrin and the compound having the structure of the formula (II-1), so as to obtain the compound having the structure represented by the formula (II).

Specific examples of the epihalohydrin include epichlorohydrin (3-chloro-1,2-epoxypropane), epibromohydrin (3-bromo-1,2-epoxypropane), or a combination of the above-mentioned compounds.

Before the dehydrohalogenation reaction is conducted, an alkali metal hydroxide such as sodium hydroxide and potassium hydroxide can be pre-added or added during the reaction process. The reaction temperature of the dehydrohalogenation reaction is 20° C. to 120° C. and the reaction time thereof is 1 hour to 10 hours.

In an embodiment, the alkali metal hydroxide added in the dehydrohalogenation reaction can also be an aqueous solution thereof. In this embodiment, when the aqueous solution of alkali metal hydroxide is continuously added in the dehydrohalogenation reaction system, water and epihalohydrin can be continuously distilled under reduced pressure or normal pressure to separate and remove water, and epihalohydrin can be continuously flown back to the reaction system.

Before the dehydrohalogenation reaction is conducted, a quaternary ammonium salt such as tetramethyl ammonium chloride, tetramethyl ammonium bromide, trimethyl benzyl ammonium chloride, etc., can also be added as a catalyst, and then an alkali metal hydroxide or an aqueous solution thereof is added after reacting for 1 hour to 5 hours at 50° C. to 150° C. Then, the mixture is reacted for 1 hour to 10 hours at 20° C. to 120° C. to proceed the dehydrohalogenation reaction.

Based on a total amount of 1 equivalent of the hydroxyl group of the compound having the structure of the formula (II-1), the usage amount of the epihalohydrin is 1 equivalent to 20 equivalents and preferably 2 equivalents to 10 equivalents. Based on a total amount of 1 equivalent of the hydroxyl group of the compound having the structure of the formula (II-1), the usage amount of the alkali metal hydroxide added in the dehydrohalogenation reaction is 0.5 equivalents to 15 equivalents and preferably 0.9 equivalents to 11 equivalents.

To proceed the dehydrohalogenation reaction smoothly, an alcohol such as methanol, ethanol, or a similar compound thereof can also be added into the reaction system. In addition, an aprotic polar solvent such as dimethyl sulfone or dimethyl sulfoxide can also be added to into the reaction system.

When alcohol is used, based on a total amount of 100 parts by weight of the epihalohydrin, the usage amount of the alcohol is 2 parts by weight to 20 parts by weight and preferably parts by weight to 15 parts by weight. When an aprotic polar solvent is used, based on a total amount of 100 parts by weight of the epihalohydrin, the usage amount of the aprotic polar solvent is 5 parts by weight to 100 parts by weight and preferably 10 parts by weight to 90 parts by weight.

After the above-mentioned dehydrohalogenation reaction is completed, a rinse treatment can be optionally conducted. Then, the epihalohydrin, the phenol, and the aprotic polar solvent are removed by using a method of heating at a temperature of 110° C. to 250° C. and at a pressure lower than 1.3 kPa (10 mmHg).

To prevent the epoxy resin formed from containing a hydrolyzable halogen, the solution after the dehydrohalogenation reaction can be added in a solvent such as toluene and methyl isobutyl ketone and an aqueous alkali metal hydroxide such as sodium hydroxide and potassium hydroxide, and then the dehydrohalogenation reaction is conducted again. In this dehydrohalogenation reaction, based on a total amount of 1 equivalent of the hydroxyl group in the compound having the structure of the formula (II-1), the usage amount of the alkali metal hydroxide is 0.01 moles to 0.3 moles and preferably 0.05 moles to 0.2 moles. Moreover, the range of the reaction temperature of the dehydrohalogenation reaction is 50° C. to 120° C. and the range of the reaction time thereof is 0.5 hours to 2 hours.

After the dehydrohalogenation reaction is completed, the salts are removed through steps such as filtering and rinsing. Moreover, solvents such as toluene and methyl isobutyl ketone can be distilled off through a method of heating under reduced pressure to obtain the compound having the structure represented by the formula (II). Specific examples of the compound having the structure represented by the formula (II) include products such as NC-3000, NC-3000H, NC-3000S, or NC-3000P made by Nippon Kayaku Co., Ltd.

Compound Having at Least One Carboxylic Group and at Least One Ethylenically Unsaturated Group (A-1-2)

The compound having at least one carboxylic group and at least one ethylenically unsaturated group (a-1-2) is selected from one of the following groups (1) to (3):

(1) acrylate, methacrylate, 2-methacryloyloxyethylbutanedioic acid, 2-methacryloyloxybutylbutanedioic acid, 2-methacryloyloxyethylhexanedioic acid, 2-methacryloyloxybutylhexanedioic acid, 2-methacryloyloxyethylhexahydrophthalic acid, 2-methacryloyloxyethylmaleic acid, 2-methacryloyloxypropylmaleic acid, 2-methacryloyloxybutylmaleic acid, 2-methacryloyloxypropylbutanedioic acid, 2-methacryloyloxypropylhexanedioic acid, 2-methacryloyloxypropyltetrahydrophthalic acid, 2-methacryloyloxypropylphthalic acid, 2-methacryloyloxybutylphthalic acid, 2-methacryloyloxybutylhydrophthalic acid, or a similar compound thereof;

(2) a compound obtained by reacting (meth)acrylate having a hydroxyl group and a dicarboxylic acid compound, wherein specific examples of the dicarboxylic acid compound include hexanedioic acid, butanedioic acid, maleic acid, phthalic acid, or a similar compound thereof;

(3) a half ester compound obtained by reacting (meth)acrylate having a hydroxyl group and the carboxylic acid anhydride compound (a-1-3) (the carboxylic acid anhydride compound can be the same as the following contents, and is therefor not repeated herein), wherein specific examples of the (meth)acrylate having a hydroxyl group include (2-hydroxyethyl)acrylate, (2-hydroxyethyl)methacrylate, (2-hydroxypropyl)acrylate, (2-hydroxypropyl)methacrylate, (4-hydroxybutyl)acrylate, (4-hydroxybutyl)methacrylate, pentaerythritol trimethacrylate, or a similar compound thereof.

Carboxylic Acid Anhydride Compound (A-1-3)

The carboxylic acid anhydride compound (a-1-3) can be selected from dicarboxylic acid anhydride compound, tetracarboxylic acid anhydride compounds, or any combination of the above-mentioned compounds.

The above-mentioned dicarboxylic acid anhydride compounds can include but are not limited to, butanedioic anhydride, maleic anhydride, itaconic anhydride, phthalic anhydride, tetrahydrophthalic anhydride, hexahydrophthalic anhydride, methyl tetrahydrophthalic anhydride, methyl hexahydrophthalic anhydride, methyl endo-methylene tetrahydrophthalic anhydride, chlorendic anhydride, glutaric anhydride, 1,3-dioxoisobenzofuran-5-carboxylic acid anhydride, or a similar compound thereof.

The above-mentioned tetracarboxylic acid anhydride compounds can include but are not limited to, benzophenone tetracarboxylic dianhydride (BTDA), dibenzenetetracarboxylic dianhydride, diphenyl ether tetracarboxylic dianhydride, or a similar compound thereof.

Compound (A-1-4) Having an Epoxy Group

Specific examples of the compound (a-1-4) having an epoxy group include glycidyl methacrylate, 3,4-epoxycyclohexyl methacrylate, a glycidyl ether compound having an unsaturated group, an unsaturated compound having an epoxy group, or a combination of the above-mentioned compounds.

Specific examples of the glycidyl ether compound having an unsaturated group include Denacol EX-111, EX-121 Denacol, Denacol EX-141, Denacol EX-145, Denacol EX-146, Denacol EX-171, or Denacol EX-192 (products of Nagase ChemteX Corporation).

### Synthesis of the Resin Having an Unsaturated Group (A-1)

The resin having an unsaturated group (A-1) can be obtained by polymerizing the epoxy compound having at least two epoxy groups (a-1-1) having the structure represented by the formula (I) and the compound having at least one carboxylic group and at least one ethylenically unsaturated group (a-1-2) to form a reaction product having a hydroxyl group, followed by adding the carboxylic acid anhydride compound (a-1-3) to proceed a reaction. Based on a total amount of 1 equivalent of the hydroxyl group of the reaction product having a hydroxyl group, the equivalent of the anhydride group contained in the carboxylic acid anhydride compound (a-1-3) is 0.4 equivalents to 1 equivalent, and preferably 0.75 equivalents to 1 equivalent. When a plurality of the carboxylic acid anhydride compounds (a-1-3) are used, the plurality of carboxylic acid anhydride compounds (a-1-3) can be added in the reaction in sequence or at the same time. When the carboxylic acid anhydride compound (a-1-3) include a dicarboxylic acid anhydride compound and a tetracarboxylic acid anhydride compound, the molar ratio of the dicarboxylic acid anhydride compound to the tetracarboxylic acid anhydride compound is 1/99 to 90/10, and preferably 5/95 to 80/20. The range of the reaction temperature is 50° C. to 130° C.

The resin having an unsaturated group (A-1) can be obtained by reacting the epoxy compound having at least two epoxy groups (a-1-1) and containing the structure represented by the formula (II) and the compound having at least one carboxylic group and at least one ethylenically unsaturated group (a-1-2) to form a reaction product having a hydroxyl group, followed by adding the carboxylic acid anhydride compound (a-1-3) and/or the compound (a-1-4) having an epoxy group to proceed a polymerization reaction. Based on a total amount of 1 equivalent of the epoxy compound having at least two epoxy groups (a-1-1) and containing the structure represented by the formula (II), the equivalent of the acid value of the compound having at least one carboxylic group and at least one ethylenically unsaturated group (a-1-2) is 0.8 equivalents to 1.5 equivalents, and preferably 0.9 equivalents to 1.1 equivalents. Based on a total amount of 100 moles of the hydroxyl group of the reaction product having a hydroxyl group, the usage amount of the carboxylic acid anhydride compound (a-1-3) is 10 moles to 100 moles, preferably 20 moles to 100 moles, and more preferably 30 moles to 100 moles.

When preparing the resin having an unsaturated group (A-1), to speed up the reaction, an alkali compound is generally added in the reaction solution as a reaction catalyst. Specific examples of the reaction catalyst include but are not limited to triphenyl phosphine, triphenyl stibine, triethylamine, triethanolamine, tetramethylammonium chloride, or benzyltriethylammonium chloride, etc. The reaction catalyst can be used alone or in any combination.

Based on a total amount of 100 parts by weight of the epoxy compound having at least two epoxy groups (a-1-1) and the compound having at least one carboxylic group and at least one ethylenically unsaturated group (a-1-2), the usage amount of the reaction catalyst is 0.01 parts by weight to 10 parts by weight and preferably 0.3 parts by weight to 5 parts by weight.

Moreover, to control the degree of polymerization, an inhibitor is generally added in the reaction solution. Specific examples of the inhibitor include but are not limited to methoxyphenol, methylhydroquinone, hydroquinone, 2,6-di-t-butyl-p-cresol, phenothiazine, or a similar compound thereof. The inhibitor can generally be used alone or in any combination.

Based on a total amount of 100 parts by weight of the epoxy compound having at least two epoxy groups (a-1-1) and the compound having at least one carboxylic group and at least one ethylenically unsaturated group (a-1-2), the usage amount of the inhibitor is 0.01 parts by weight to 10 parts by weight and preferably 0.1 parts by weight to 5 parts by weight.

When preparing the resin having an unsaturated group (A-1), a polymerization reaction solvent can be added into the reaction solution. Specific examples of the polymerization reaction solvent include but are not limited to alcohol compounds such as ethanol, propanol, isopropanol, butanol, isobutanol, 2-butanol, hexanol, ethylene glycol, or a similar compound thereof; ketone compounds such as methyl ethyl ketone, cyclohexanone, or a similar compound thereof; aromatic hydrocarbon compounds such as toluene, xylene, or a similar compound thereof; cellosolve compounds such as cellosolve, butyl cellosolve, or a similar compound thereof; carbitol compounds such as carbitol, butyl carbitol, or a similar compound thereof; propylene glycol alkyl ether compounds such as propylene glycol monomethyl ether or a similar compound thereof; poly(propylene glycol)alkyl ether compounds such as di(propylene glycol) methyl ether or a similar compound thereof; acetic acid ester compounds such as ethyl acetate, butyl acetate, ethylene glycol monoethyl ether acetate, propylene glycol monomethyl ether acetate, or a similar compound thereof; alkyl lactate compounds such as ethyl lactate, butyl lactate, or a similar compound thereof; or dialkyl glycol ethers. The polymerization reaction solvent can be used alone or in any combination.

The acid value of the resin (A-1) of the present invention having an unsaturated group is 50 mgKOH/g to 150 mgKOH/g.

Based on a usage amount of 100 parts by weight of the alkai-soluble resin (A), the usage amount of the resin having an unsaturated group (A-1) is 30 parts by weight to 100 parts by weight, preferably 50 parts by weight to 100 parts by weight, and more preferably 70 parts by weight to 100 parts by weight.

When the resin having an unsaturated group (A-1) is not included in the alkali-soluble resin (A) of the present invention, the photosensitive resin composition has a poor heat-enduring resistance stability.

Other Alkali-Soluble Resins (A-2)

The other alkali-soluble resins (A-2) include but are not limited to resins having a carboxylic group or a hydroxyl group. Specific examples of the other alkai-soluble resins (A-2) include alkali-soluble resins other than the resin having an unsaturated group (A-1) such as acrylic-based resin, urethane-based resin, or novolac resin, etc.

Based on a usage amount of 100 parts by weight of the alkai-soluble resin (A), the usage amount of the other alkali-soluble resins (A-2) is 0 parts by weight to 70 parts by weight, preferably 0 parts by weight to 50 parts by weight, and more preferably 0 parts by weight to 30 parts by weight.

### Compound Having an Ethylenically Unsaturated Group (B) Compound Having an Ethylenically Unsaturated Group (B)

The compound having an ethylenically unsaturated group (B) compound having an ethylenically unsaturated group (B) can include a compound (B-1) having one ethylenically unsaturated group or a compound (B-2) having at least two (including two)ethylenically unsaturated groups.

Specific examples of the compound (B-1) having one ethylenically unsaturated group include but are not limited to (meth)acrylamide, (meth)acryloylmorpholine, 7-amino-3,7-dimethyloctyl(meth)acrylate, isobutoxymethyl(meth)acrylamide, isobornyloxyethyl(meth)acrylate, isobornyl(meth)acrylate, 2-ethylhexyl(meth)acrylate, ethyl diethylene glycol(meth)acrylate, t-octyl(meth)acrylamide, diacetone(meth)acrylamide, dimethylaminoethyl(meth)acrylate, dodecyl(meth)acrylate, dicyclopentenyloxyethyl(meth)acrylate, dicyclopentenyl(meth)acrylate, N,N-dimethyl(meth)acrylamide, tetrachlorophenyl(meth)acrylate, 2-tetrachlorophenoxy ethyl(meth)acrylate, tetrahydrofurfuryl(meth)acrylate, tetrabromophenyl(meth)acrylate, 2-tetrabromophenoxyethyl(meth)acrylate, 2-trichlorophenoxyethyl(meth)acrylate, tribromophenyl(meth)acrylate, 2-tribromophenoxyethyl(meth)acrylate, 2-hydroxyethyl(meth)acrylate, 2-hydroxypropyl(meth)acrylate, vinylcaprolactam, N-vinylpyrrolidone, phenoxyethyl(meth)acrylate, pentachlorophenyl(meth)acrylate, pentabromophenyl(meth)acrylate, polyethylene glycol mono(meth)acrylate, polypropylene glycol mono(meth)acrylate, or bornyl(meth)acrylate. The compound (B-1) having one ethylenically unsaturated group can be used alone or in any combination.

Specific examples of the compound (B-2) having at least two (including two) ethylenically unsaturated groups include but are not limited to ethylene glycol di(meth)acrylate, dicyclopentenyl di(meth)acrylate, triethylene glycol di(meth)acrylate, tetraethylene glycol di(meth)acrylate, tri(2-hydroxyethyl)isocyanate di(meth)acrylate, tri(2-hydroxyethyl)isocyanate tri(meth)acrylate, caprolactone-modified tri(2-hydroxyethyl)isocyanate tri(meth)acrylate, trimethylolpropyl tri(meth)acrylate, ethylene oxide (EO) modified trimethylolpropyl tri(meth)acrylate, propylene oxide (PO) modified trimethylolpropyl tri(meth)acrylate, tripropylene glycol di(meth)acrylate, neo-pentyl glycol di(meth)acrylate, 1,4-butanediol di(meth)acrylate, 1,6-hexanediol di(meth)acrylate, pentaerythritol tri(meth)acrylate, pentaerythritol tetra(meth)acrylate, polyester di(meth)acrylate, polyethylene glycol di(meth)acrylate, dipentaerythritol hexa(meth)acrylate, dipentaerythritol penta(meth)acrylate, dipentaerythritol tetra(meth)acrylate, caprolactone-modified dipentaerythritol hexa(meth)acrylate, caprolactone-modified dipentaerythritol penta(meth)acrylate, di(trimethylolpropyl)tetra(meth)acrylate, EO-modified bisphenol A di(meth)acrylate, PO-modified bisphenol A di(meth)acrylate, EO-modified hydrogenated bisphenol A di(meth)acrylate, PO-modified hydrogenated bisphenol A di(meth)acrylate, PO-modified glycerol tri(meth)acrylate, EO-modified bisphenol F di(meth)acrylate, polyglycidyl(meth)acrylate of novolac resin, or any combination of the above-mentioned compounds. The compound (B-2) having at least two (including two) ethylenically unsaturated groups can be used alone or in any combination.

Specific examples of the compound having an ethylenically unsaturated group (B) compound having an ethylenically unsaturated group (B) include trimethylolpropyl triacrylate, EO-modified trimethylolpropyl triacrylate, PO-modified trimethylolpropyl triacrylate, pentaerythritol triacrylate, pentaerythritol tetraacrylate, dipentaerythritol hexaacrylate, dipentaerythritol pentaacrylate, dipentaerythritol tetraacrylate, caprolactone-modified dipentaerythritol hexaacrylate, di(trimethylolpropyl)tetraacrylate, PO-modified glycerol triacrylate, or any combination of the above-mentioned compounds.

The compound having an ethylenically unsaturated group (B) compound having an ethylenically unsaturated group (B) is preferably trimethylolpropyl triacrylate, dipentaerythritol tetracrylate, dipentaerythritol hexaacrylate, or any combination of the above-mentioned compounds.

Based on a usage amount of 100 parts by weight of the alkali-soluble resin (A), the usage amount of the compound having an ethylenically unsaturated group (B) compound having an ethylenically unsaturated group (B) is 20 parts by weight to 160 parts by weight, preferably 25 parts by weight to 140 parts by weight, and more preferably 30 parts by weight to 120 parts by weight.

### Photoinitiator (C)

The photoinitiator (C) of the present invention can be a substance producing a free radical through irradiation. Moreover, the substance having a free radical can initiate a cross-linking reaction between polymers, between a polymer and an oligomer, and between a polymer and a monomer, thereby forming a hardened layer (such as a black matrix) having excellent mechanical strength.

Specific examples of the photoinitiator (C) include an O-acyloxime compound, a triazine compound, a acetophenone compound, a diimidazole compound, a benzophenone compound, an α-diketone compound, a ketol compound, an acyloin ether compound, an acylphosphine oxide compound, a quinone compound, a halogen-containing compound, peroxide, or any combination of the above-mentioned compounds.

Specific examples of the O-oxime compound include
1-[4-(phenylthio)phenyl]-heptane-1,2-dione 2-(O-benzoyloxime),
1-[4-(phenylthio)phenyl]-octane-1,2-dione 2-(O-benzoyloxime),
1-[4-(benzoyl)phenyl]-heptane-1,2-dione 2-(O-benzoyloxime),
1-[9-ethyl-6-(2-methylbenzoyl)-9H-carbazol-3-yl]-ethanone 1-(O-acetyloxime),
1-[9-ethyl-6-(3-methylbenzoyl)-9H-carbazol-3-yl]-ethanone 1-(O-acetyloxime),
1-[9-ethyl-6-benzoyl-9H-carbazol-3-yl]-ethanone 1-(O-acetyloxime),
ethanone-1-[9-ethyl-6-(2-methyl-4-(tetrahydrofuranyl)benzoyl)-9H-carbazol-3-yl]-1-(O-acetyloxime),
ethanone-1-[9-ethyl-6-(2-methyl-4-(tetrahydropyranyl)benzoyl)-9H-carbazol-3-yl]-1-(O-acetyloxime),
ethanone-1-[9-ethyl-6-(2-methyl-5-(tetrahydrofuranyl)benzoyl)-9H-carbazol-3-yl]-1-(O-acetyloxime),
ethanone-1-[9-ethyl-6-(2-methyl-5-(tetrahydropyranyl)benzoyl)-9H-carbazol-3-yl]-1-(O-acetyloxime),
ethanone-1-[9-ethyl-6-(2-methyl-4-(tetrahydrofuranyl)methoxybenzoyl)-9H-carbazol-3-yl]-1-(O-acetyloxime),
ethanone-1-[9-ethyl-6-(2-methyl-4-(tetrahydropyranyl)methoxybenzoyl)-9H-carbazol-3-yl]-1-(O-acetyloxime),
ethanone-1-[9-ethyl-6-(2-methyl-5-(tetrahydrofuranyl)methoxybenzoyl)-9H-carbazol-3-yl]-1-(O-acetyloxime),
ethanone-1-[9-ethyl-6-(2-methyl-5-(tetrahydropyranyl)methoxybenzoyl)-9H-carbazol-3-yl]-1-(O-acetyloxime),
ethanone-1-[9-ethyl-6-{2-methyl-4-(2,2-dimethyl-1,3-dioxacyclopentyl)benzoyl}-9H-carbazol-3-yl]-1-(O-acetyloxime),
ethanone-1-[9-ethyl-6-{2-methyl-4-(2,2-dimethyl-1,3-dioxacyclopentyl)methoxybenzoyl}-9H-carbazol-3-yl]-1-(O-acetyloxime), or any combination of the above-mentioned compounds.

The O-oxime compound is preferably 1-[4-(phenylthio)phenyl]-octane-1,2-dione-2-(O-benzoyloxime) (product name: OXE-01, made by Ciba Specialty Chemicals Co., Ltd.), 1-[9-ethyl-6-(2-methylbenzoyl)-9H-carbazol-3-yl]-ethanone 1-(O-acetyloxime) (product name: OXE-02, made by Ciba Specialty Chemicals Co., Ltd.), ethanone-1-[9-ethyl-6-(2-methyl-4-(tetrahydrofuranyl)methoxybenzoyl)-9H-carbazol-3-yl]-1-(O-acetyloxime), ethanone-1-[9-ethyl-6-{2-methyl-4-(2,2-dimethyl-1,3-dioxacyclopentyl)methoxybenzoyl}-9H-carbazol-3-yl]-1-(O-acetyloxime), or any combination of the above-mentioned compounds. The O-oxime compound can be used alone or in any combination.

Specific examples of the triazine compound include a vinyl halomethyl-s-triazine compound, a 2-(naphtho-1-yl)-4,6-dihalomethyl-s-triazine compound, a 4-(p-aminophenyl)-2,6-dihalomethyl-s-triazine compound, or a similar compound thereof, or any combination of the above-mentioned compounds.

Specific examples of the vinyl halomethyl-s-triazine compound include 2,4-bis(trichloromethyl)-6-p-methoxystyryl-s-triazine, 2,4-bis(trichloromethyl)-3-(1-p-dimethylaminophenyl-1,3-butadienyl)-s-triazine, 2-trichloromethyl-3-amino-6-p-methoxystyryl-s-triazine, or a similar compound thereof, or any combination of the above-mentioned compound.

Specific examples of the 2-(naphtho-1-yl)-4,6-dihalomethyl-s-triazine compound include 2-(naphtho-1-yl)-4,6-bis-trichloromethyl-s-triazine, 2-(4-methoxy-naphtho-1-yl)-4,6-bis-trichloromethyl-s-triazine, 2-(4-ethoxy-naphtho-1-yl)-4,6-bis-trichloromethyl-s-triazine, 2-(4-butoxy-naphtho-1-yl)-4,6-bis-trichloromethyl-s-triazine, 2-(4-(2-methoxyethyl)-naphtho-1-yl)-4,6-bis-trichloromethyl-s-triazine, 2-(4-(2-ethoxyethyl)-naphtho-1-yl)-4,6-bis-trichloromethyl-s-triazine, 2-(4-(2-butoxyethyl)-naphtho-1-yl)-4,6-bis-trichloromethyl-s-triazine, 2-(2-methoxy-naphtho-1-yl)-4,6-bis-trichloromethyl-s-triazine, 2-(6-methoxy-5-methyl-naphtho-2-yl)-4,6-bis-trichloromethyl-s-triazine, 2-(6-methoxynaphtho-2-yl)-4,6-bis-trichloromethyl-s-triazine, 2-(5-methoxy-naphtho-1-yl)-4,6-bis-trichloromethyl-s-triazine, 2-(4,7-dimethoxy-naphtho-1-yl)-4,6-bis-trichloromethyl-s-triazine, 2-(6-ethoxy-naphtho-2-yl)-4,6-bis-trichloromethyl-s-triazine, 2-(4,5-dimethoxy-naphtho-1-yl)-4,6-bis-trichloromethyl-s-triazine, or a similar compound thereof, or any combination of the above-mentioned compounds.

Specific examples of the 4-(p-aminophenyl)-2,6-dihalomethyl-s-triazine compound include 4-(p-N,N-di(ethoxycarbonylmethyl)aminophenyl)-2,6-di(trichloromethyl)-s-triazine, 4-(o-methyl-p-N,N-di(ethoxycarbonylmethyl)aminophenyl)-2,6-di(trichloromethyl)-s-triazine, 4-(p-N,N-di(chloroethyl)aminophenyl)-2,6-di(trichloromethyl)-s-triazine, 4-(o-methyl-p-N,N-di(chloroethyl)aminophenyl)-2,6-di(trichloromethyl)-s-triazine, 4-(p-N-chloroethylaminophenyl)-2,6-di(trichloromethyl)-s-triazine, 4-(p-N-ethoxycarbonylmethylaminophenyl)-2,6-di(trichloromethyl)-s-triazine, 4-(p-N,N-di(phenyl)aminophenyl)-2,6-di(trichloromethyl)-s-triazine, 4-(p-N-chloroethylcarbonylaminophenyl)-2,6-di(trichloromethyl)-s-triazine, 4-(p-N-(p-methoxyphenyl)carbonylaminophenyl)-2,6-di(trichloromethyl)-s-triazine, 4-(m-N,N-di(ethoxycarbonylmethyl)aminophenyl)-2,6-di(trichloromethyl)-s-triazine, 4-(m-bromo-p-N,N-di(ethoxycarbonylmethyl)aminophenyl)-2,6-di(trichloromethyl)-s-triazine, 4-(m-chloro-p-N,N-di(ethoxycarbonylmethyl)aminophenyl)-2,6-di(trichloromethyl)-s-triazine, 4-(m-fluoro-p-N,N-di(ethoxycarbonylmethyl)aminophenyl)-2,6-di(trichloromethyl)-s-triazine, 4-(o-bromo-p-N,N-di(ethoxycarbonylmethyl)aminophenyl)-2,6-di(trichloromethyl)-s-triazine, 4-(o-chloro-p-N,N-di(ethoxycarbonylmethyl)aminophenyl)-2,6-di(trichloromethyl)-s-triazine, 4-(o-fluoro-p-N,N-di(ethoxycarbonylmethyl)aminophenyl)-2,6-di(trichloromethyl)-s-triazine, 4-(o-bromo-p-N,N-di(chloroethyl)aminophenyl)-2,6-di(trichloromethyl)-s-triazine, 4-(o-chloro-p-N,N-di(chloroethyl)aminophenyl)-2,6-di(trichloromethyl)-s-triazine, 4-(o-fluoro-p-N,N-di(chloroethyl)aminophenyl)-2,6-di(trichloromethyl)-s-triazine, 4-(m-bromo-p-N,N-di(chloroethyl)aminophenyl)-2,6-di(trichloromethyl)-s-triazine, 4-(m-chloro-p-N,N-di(chloroethyl)aminophenyl)-2,6-di(trichloromethyl)-s-triazine, 4-(m-fluoro-p-N,N-di(chloroethyl)aminophenyl)-2,6-di(trichloromethyl)-s-triazine, 4-(m-bromo-p-N-ethoxycarbonylmethylaminophenyl)-2,6-di(trichloromethyl)-s-triazine, 4-(m-chloro-p-N-ethoxycarbonylmethylaminophenyl)-2,6-di(trichloromethyl)-s-triazine, 4-(m-fluoro-p-N-ethoxycarbonylmethylaminophenyl)-2,6-di(trichloromethyl)-s-triazine, 4-(o-bromo-p-N-ethoxycarbonylmethylaminophenyl)-2,6-di(trichloromethyl)-s-triazine, 4-(o-chloro-p-N-ethoxycarbonylmethylaminophenyl)-2,6-di(trichloromethyl)-s-triazine, 4-(o-fluoro-p-N-ethoxycarbonylmethylaminophenyl)-2,6-di(trichloromethyl)-s-triazine, 4-(m-bromo-p-N-chloroethylaminophenyl)-2,6-di(trichloromethyl)-s-triazine, 4-(m-chloro-p-N-chloroethylaminophenyl)-2,6-di(trichloromethyl)-s-triazine, 4-(m-fluoro-p-N-chloroethylaminophenyl)-2,6-di(trichloromethyl)-s-triazine, 4-(o-bromo-p-N-chloroethylaminophenyl)-2,6-di(trichloromethyl)-s-triazine, 4-(o-chloro-p-N-chloroethylaminophenyl)-2,6-di(trichloromethyl)-s-triazine, 4-(o-fluoro-p-N-chloroethylaminophenyl)-2,6-di(trichloromethyl)-s-triazine, 2,4-di(trichloromethyl)-6-(3-bromo-4-(N,N-di(ethoxycarbonylmethyl)amino)phenyl)-1,3,5-triazine, or a similar compound thereof, or any combination of the above-mentioned compounds.

The triazine compound is preferably 4-(m-bromo-p-N,N-di(ethoxycarbonylmethyl)aminophenyl)-2,6-di(trichloromethyl)-s-triazine, 2,4-di(trichloromethyl)-6-p-methoxystyryl-s-triazine, or a combination of the above-mentioned compounds. The triazine compound can be used alone or in any combination.

Specific examples of the acetophenone compound include p-dimethylamino-acetophenone, α,α′-dimethoxyazoxy-acetophenone, 2,2′-dimethyl-2-phenyl-acetophenone, p-methoxy-acetophenone, 2-benzyl-2-N,N-dimethylamino-1-(4-morpholinophenyl)-1-butanone, 2-methyl-1-(4-methylthio phenyl)-2-morpholino-1-propanone, or a similar compound thereof, or any combination of the above-mentioned compounds. The acetophenone compound is preferably 2-methyl-1-(4-methylthio)phenyl-2-morpholinyl-1-propanone or 2-benzyl-2-N,N-dimethylamino-1-(4-morpholino phenyl)-1-butanone. The acetophenone compound can be used alone or in any combination.

Specific examples of the diimidazole compound include 2,2′-bis(o-chlorophenyl)-4,4′,5,5′-tetraphenyldiimidazole, 2,2′-bis(o-fluorophenyl)-4,4′,5,5′-tetraphenyldiimidazole, 2,2′-bis(o-methylphenyl)-4,4′,5,5′-tetraphenyldiimidazole, 2,2′-bis(o-methoxyphenyl)-4,4′,5,5′-tetraphenyldiimidazole, 2,2′-bis(o-ethylphenyl)-4,4′,5,5′-tetraphenyldiimidazole, 2,2′-bis(p-methoxyphenyl)-4,4′,5,5′-tetraphenyldiimidazole, 2,2′-bis(2,2′,4,4′-tetramethoxyphenyl)-4,4′,5,5′-tetraphenyldiimidazole, 2,2′-bis(2-chlorophenyl)-4,4′,5,5′-tetraphenyldiimidazole, 2,2′-bis(2,4-dichlorophenyl)-4,4′,5,5′-tetraphenyldiimidazole, or a similar compound thereof, or any combination of the above-mentioned compounds. The diimidazole compound can be used alone or in any combinations. The diimidazole compound is preferably 2,2′-bis(2,4-dichlorophenyl)-4,4′,5,5′-tetraphenyldiimidazole.

Specific examples of the benzophenone compound include thioxanthone, 2,4-diethylthioxanthone, thioxanthone-4-sulfone, benzophenone, 4,4′-bis(dimethylamino)benzophenone, 4,4′-bis(diethylamino)benzophenone, or a similar compound thereof, or any combination of the above-mentioned compounds. The benzophenone compound can be used alone or in any combination. The benzophenone compound is preferably 4,4′-bis(diethylamino)benzophenone.

Specific examples of the α-diketone compounds include diphenyl-ethanedione or a compound having an acetyl group.

Specific examples of the acyloin ether compound include benzoin.

Specific examples of the acyloin ether compound include benzoin methyl ether, benzoin ethyl ether, benzoin isopropyl ether, or a similar compound thereof, or any combination of the above-mentioned compounds.

Specific examples of the acylphosphine oxide compound include (2,4,6-trimethylbenzoyl)diphenylphosphine oxide, bis(2,6-dimethoxybenzoyl)-2,4,4-trimethylpentylphosphine oxide, or a similar compound thereof, or any combination of the above-mentioned compounds.

Specific examples of the quinone compound include anthraquinone, 1,4-naphthoquinone, or a similar compound thereof, or any combination of the above-mentioned compounds.

Specific examples of the halogen-containing compound include phenacyl chloride, tribromomethyl phenyl sulfone, tris(trichloromethyl)-s-triazine, or a similar compound thereof, or any combination of the above-mentioned compounds.

Specific examples of the peroxide include di-tert-butyl peroxide and a similar compound thereof.

The photoinitiator (C) is preferably 1-[9-ethyl-6-(2-methylbenzoyl)-9H-carbazol-3-yl]-ethanone 1-(O-acetyloxime) (product name: OXE-02, made by Ciba Specialty Chemicals Co., Ltd.), 1-[4-(phenylthio)phenyl]-octane-1,2-dione 2-(O-benzoyloxime) (product name: OXE-01, made by Ciba Specialty Chemicals Co., Ltd.), 2-methyl-1-[4-(methylthio)phenyl]-2-morpholino-1-propanone (product name: IRGACURE 907, made by Ciba Specialty Chemicals Co., Ltd.), or any combination of the above-mentioned compounds.

Based on a usage amount of 100 parts by weight of the alkali-soluble resin (A), the usage amount of the photoinitiator (C) is 10 to 60 parts by weight, preferably 12 to 50 parts by weight, and more preferably 15 to 40 parts by weight.

### Solvent (D)

The solvent (D) of the present invention refers to a solvent that can dissolve the alkali-soluble resin (A), the compound having an ethylenically unsaturated group (B) compound having an ethylenically unsaturated group (B), and the photoinitiator (C) but does not react with the black pigment (E) and the fluorescent brightening agent (F). The solvent (D) preferably has a suitable volatility.

Specific examples of the solvent (D) include an alkylene glycol monoalkyl ether compound, an alkylene glycol monoalkyl ether acetate compound, diethylene glycol alkyl ether, other ether compounds, a ketone compound, a alkyl lactate compound, other ester compounds, an aromatic hydrocarbon compound, a carboxylic acid amine compound, or any combination of the above-mentioned compounds. The solvent (D) can be used alone or in any combination.

Specific examples of the alkyl glycol monoalkyl ether compound include ethylene glycol monomethyl ether, ethylene glycol monoethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol mono-n-propyl ether, dipropylene glycol monon-butyl ether, tripropylene glycol monomethyl ether, tripropylene glycol monoethyl ether, or a similar compound thereof, or any combination of the above-mentioned compounds.

Specific examples of the alkyl glycol monoalkyl ether acetate compound include ethylene glycol monomethyl ether acetate, ethylene glycol monoethyl ether acetate, propylene glycol monomethyl ether acetate, propylene glycol monoethyl ether acetate, or a similar compound thereof, or any combination of the above-mentioned compounds.

Specific examples of the diethylene glycol alkyl ether include diethylene glycol dimethyl ether, diethylene glycol ethyl methyl ether, diethylene glycol diethyl ether, or a similar compound thereof, or any combination of the above-mentioned compounds.

Specific examples of the other ether compounds include tetrahydrofuran or a similar compound thereof.

Specific examples of the ketone compound include methyl ethyl ketone, cyclohexanone, 2-heptanone, 3-heptanone, diacetone alcohol, or a similar compound thereof, or any combination of the above-mentioned compounds.

Specific examples of the alkyl lactate compound include methyl lactate, ethyl lactate, or a similar compound thereof, or any combination of the above-mentioned compounds.

Specific examples of the other ester compounds include methyl 2-hydroxy-2-methylpropanoate, ethyl 2-hydroxy-2-methylpropanoate, methyl 3-methoxypropanoate, ethyl 3-methoxypropanoate, methyl 3-ethoxypropanoate, ethyl 3-ethoxypropanoate, ethyl ethoxyacetate, ethyl hydroxyacetate, methyl 2-hydroxy-3-methylbutyrate, 3-methyl-3-methoxybutyl acetate, 3-methyl-3-methoxybutyl propanoate, ethyl acetate, n-propyl acetate, isopropyl acetate, n-butyl acetate, isobutyl acetate, n-amyl acetate, isoamyl acetate, n-butyl propanoate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, ethyl 2-oxybutyrate, or a similar compound thereof, or any combination of the above-mentioned compounds.

Specific examples of the aromatic hydrocarbon compound include toluene, xylene, or a similar compound thereof, or any combination of the above-mentioned compounds.

Specific examples of the carboxylic acid amine compound include N-methylpyrrolidone, N,N-dimethyl formamide, N,N-dimethyl acetamide, or a similar compound thereof, or any combination of the above-mentioned compounds.

The solvent (D) is preferably propylene glycol monomethyl ether acetate or ethyl 3-ethoxypropionate.

Based on a usage amount of 100 parts by weight of the alkali-soluble resin (A), the usage amount of the solvent (D) is 400 parts by weight to 4000 parts by weight, preferably 500 parts by weight to 3500 parts by weight, and more preferably 600 parts by weight to 3000 parts by weight.

### Black Pigment (E)

The black pigment (E) of the present invention is preferably a black pigment having a good heat resistance, light resistance, and solvent resistance.

Specific examples of the black pigment (E) include organic black organic pigments such as perylene black, cyanine black, or aniline black; a near-black mixture of organic pigments obtained by mixing two or more pigments selected from the pigments of red, blue, green, purple, yellow, cyanine, or magenta; light-shielding materials such as carbon black, chromium oxide, ferric oxide, titanium black, or graphite.

Specific examples of the carbon black include C.I. pigment black 7 or commercial products made by Mitsubishi Chemical Corporation (product names MA100, MA230, MA8, #970, #1000, #2350, or #2650). The black pigment (E) can be used alone or in multiple combinations.

The black pigment (F) is preferably carbon black or the commercial product MA100 or MA230.

Based on a usage amount of 100 parts by weight of the alkali-soluble resin (A), the usage amount of the black pigment (E) is 60 parts by weight to 600 parts by weight, preferably 80 parts by weight to 500 parts by weight, and more preferably 100 parts by weight to 400 parts by weight.

### Fluorescent Brightening Agent (F)

The fluorescent brightening agent (F) of the present invention is preferably a compound absorbing UV light. The fluorescent brightening agent (F) absorbs the light of which the wavelength is between 300 nm and 390 nm and in the UV region of the spectrum. After the fluorescent brightening agent (F) absorbs light, it irradiates a visible light having a wavelength of 400 nm to 525 nm.

The fluorescent brightening agent (F) is selected from at least one of stilbene derivatives, coumarin derivatives, and benzoxazole derivatives.

Specific examples of the stilbene derivatives include but are not limited to 4,4′-bis[(4-anilino-6-(2-hydroxyethyl)methylamino-1,3,5-triazin-2-yl)amino]stilbene-2,2′-disulfonic sodium, 4,4′-bis[anilino-6-morpholine-1,3,5-triazin-2-yl]amino]stilbene, 4,4′-bis[(4-anilino-6-bis(2-hydroxyethyl)amino-1,3,5-triazin-2-yl)amino]stilbene-2,2′-d isulphonic acid, 4,4′-bis[(4,6-dianilino-1,3,5-triazin-2-yl)amino]stilbene-2,2′-disulfonic sodium, 4,4′-distyrylbiphenyl disulfonic sodium or the stilbene derivative of naphthotriazole (TINOPAL GS from Ciba).

Specific examples of the coumarin derivatives include but are not limited to 4-methyl-7-diethylcoumarin, diethylaminomethylcoumarin, 3-phenyl-7-(4-methyl-6-butoxy benzoxazole)coumarin, 3-phenyl-7-[2H-naphtho-(1,2-d)triazol-2-yl]coumarin or the cationic derivative of aminocoumarin (Tinopal SWN Conc. From Ciba).

Specific examples of the benzoxazole derivatives include but are not limited to 2,5-thiophenediyl-bis(5-tert-butyl-1,3-benzoxazole, benzoxazole-2,2′-(2,5-thiophenediyl)-bis[5-(1,1-dimethylethyl)], 2,2′-[(1,2-ethenediyl)bis(4,1-phenylene)]bis-benzoxazole), 2,2′-(2,5-thiophenediyl)bis-(5-tert-butyl-benzoxazole)-1,4,5,8-naphthalene-tetracarboxylic imide, 3-phenyl-7-(4-methyl-6-butoxy benzoxazole)coumarin. The fluorescent brightening agent (F) can be used alone or in any combination.

Preferably, the fluorescent brightening agent (F) is diethylaminomethylcoumarin, 4-methyl-7-diethylcoumarin, 4,4′-bis[(4,6-dianilino-1,3,5-triazin-2-yl)amino]stilbene-2,2′-disulfonic sodium, 4,4′-bis[(4-anilino-6-(2-hydroxyethyl)methylamino-1,3,5-triazin-2-yl)amino]stilbene-2,2′-disulfonic sodium, 4,4′-distyrylbiphenyl disulfonic sodium, 2,5-thiophenediyl-bis(5-tert-butyl-1,3-benzoxazole, benzoxazole-2,2′-(2,5-thiophenediyl)-bis[5-(1,1-dimethylethyl)] and/or any combination of the above-mentioned compound.

Based on a usage amount of 100 parts by weight of alkali-soluble resin (A), the usage amount of the fluorescent brightening agent (F) is 0.1 parts by weight to 5 parts by weight, and preferably 0.3 parts by weight to 4.5 parts by weight, and more preferably 0.5 parts by weight to 4 parts by weight.

If the photosensitive resin composition does not include fluorescent brightening agent (F), the photosensitive resin composition formed has a poor heat-enduring resistance stability.

### Additive (G)

Under the premise of not affecting the efficacy of the present invention, the photosensitive resin composition for black matrix of the present invention can optionally further include an additive (G). Specific examples of the additive (G) include a surfactant, a filler, an adhesion promoter, an antioxidant, an anticoagulant, or other polymers capable of enhancing various properties (such as mechanical properties) other than the alkali-soluble resin (A).

Specific examples of the surfactant include a cationic surfactant, an anionic surfactant, a nonionic surfactant, a amphoteric surfactant, a polysiloxane surfactant, a fluorine series surfactant, or any combination of the above-mentioned surfactants.

Specific examples of the surfactant include polyoxyethylene alkyl ethers such as polyoxyethylene lauryl ether, polyoxyethylene stearyl ether, polyoxyethylene oleyl ether, or a similar compound thereof; polyoxyethylene alkyl phenyl ethers such as polyoxyethylene octyl phenyl ether, polyoxyethylene nonyl phenyl ether, or a similar compound thereof; polyethylene glycol diesters such as polyethylene glycol dilaurate, polyethylene glycol stearyl ether, or a similar compound thereof; sorbitan fatty acid esters; fatty acid-modified polyesters; or tertiary amine-modified polyurethanes; or commercially available products. The commercially available products include KP products made by Shin-Etsu Chemical Co., Ltd., SF-8427 products made by Dow Corning Toray Co., Ltd., Polyflow products made by Kyoeisha Chemical Co. Ltd., F-Top products made by Tochem Products Co., Ltd., Megafac products made by DIC Corporation, Fluorade products made by Sumitomo 3M Limited, Asahi Guard products made by Asahi Glass Co., Ltd., or Surflon products made by Asahi Glass Co., Ltd. The surfactant can be used alone or in any combination.

Specific examples of the filler include glass or aluminum.

Specific examples of the adhesion promoter include vinyltrimethoxysilane, vinyltriethoxysilane, vinyl-tris(2-methoxyethoxy)silane, N-(2-amino ethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane (KBM-403 from Shin-Etsu), 3-glycidoxypropylmethyldiethoxysilane, 2-(3,4-epoxycyclohexypethyltrimethoxysilane, 3-chloropropylmethyldimethoxysilane, 3-chloropropyltrimethoxysilane, 3-methyl propionyloxy propyltrimethoxysilane, 3-mercaptopropyltrimethoxysilane, or a similar compound thereof, or any combination of the above-mentioned compounds.

Specific examples of the antioxidant include 2,2′-thiobis(4-methyl-6-tert-butylphenol), 2,6-di-tert-butylphenol, or any combination of the above-mentioned compounds.

Specific examples of the anticoagulant include sodium polyacrylate.

Based on a usage amount of 100 parts by weight of the alkali-soluble resin (A), the range of the usage amount of the filler, the adhesion promoter, the antioxidant, the anticoagulant, and the polymer other than the alkali-soluble resin (A) in the additive (G) is less than 10 parts by weight and preferably less than 6 parts by weight.

### Preparation Method of Photosensitive Resin Composition for Black Matrix

The method for preparing the photosensitive resin composition for black matrix includes placing and stirring the alkai-soluble resin (A), the compound having an ethylenically unsaturated group (B) compound having an ethylenically unsaturated group (B), the photoinitiator (C), the solvent (D), the black pigment (E), and the fluorescent brightening agent (F) in a stirrer such that the components are uniformly mixed into a solution. The additive (G) can be added if necessary. After the solution is uniformly mixed, the photosensitive resin composition (in solution state) for black matrix can be obtained.

In addition, the preparation method of the photosensitive resin composition for black matrix is not particularly limited. The photosensitive resin composition for black matrix can be formed by directly adding and dispersing the black pigment (E) in the mixture composed of the alkali-soluble resin (A), the compound having an ethylenically unsaturated group (B) compound having an ethylenically unsaturated group (B), the photoinitiator (C), the solvent (D), and the fluorescent brightening agent (F). Alternatively, the photosensitive resin composition (in solution state) for a black matrix can be prepared by first dispersing a portion of the black pigment (E) in a mixture composed of a portion of the alkali-soluble resin (A) and a portion of the solvent (D) to form a pigment dispersion liquid, and then adding the rest of the alkali-soluble resin (A), the compound having an ethylenically unsaturated group (B), the photoinitiator (C), the remaining solvent (D), the remaining black pigment, and the fluorescent brightening agent (F).

Moreover, the dispersion steps of the black pigment (E) can be conducted by mixing with a mixer such as a beads mill or a roll mill.

### Preparation of Black Matrix

The black matrix is prepared by applying the photosensitive resin composition for black matrix on a substrate and treating it with pre-bake, exposure, development, and post-bake. When the film thickness of the obtained black matrix is 1 μm, the range of the optical density can be greater than 3.0, preferably 3.2 to 5.5, and more preferably 3.5 to 5.5. The preparation method of the black matrix is described in detail below.

Firstly, the photosensitive resin composition in liquid state for a black matrix is uniformly coated on a substrate by a coating method such as spin coating or cast coating to form a coating film. Specific examples of the substrate include alkali-free glass, soda-lime glass, hard glass (Pyrex glass), silica glass, and glasses with a transparent conductive film attached thereto, or a substrate (e.g., a silicon substrate) used for a photoelectric conversion device such as a solid imaging device.

After the coating film is formed, most of the solvent is removed by drying under reduced pressure. Next, the remaining solvent is completely removed by a pre-bake process to form a pre-baked coating film. It should be mentioned that, the conditions for drying under reduced pressure and pre-baking can vary according to the components and the ratio of each component. Generally, drying under reduced pressure is conducted at a pressure of less than 200 mmHg for 1 second to 20 seconds, and the pre-bake is a heat treatment conducted on the coating film at a temperature of 70° C. to 110° C. for 1 minute to 15 minutes.

Then, the pre-baked coating film is exposed with a photomask having a specific pattern. The light used in the exposure process is preferably an ultraviolet light such as a g-line, an h-line, or an i-line. In addition, the UV light irradiation device can be a(n) (ultra-)high pressure mercury vapor lamp or a metal halide lamp.

Then, the exposed pre-baked coating film is immersed in a developing solution at a temperature of 23±2° C. to remove the unexposed portion of the pre-baked coating film and to form a specific pattern on the substrate.

The above-mentioned developing solution can include an alkali compound such as sodium hydroxide, potassium hydroxide, sodium carbonate, sodium hydrogen carbonate, potassium carbonate, potassium hydrogen carbonate, sodium silicate, sodium methylsilicate, ammonia solution, ethylamine, diethylamine, dimethylethylanolamine, tetramethylammonium hydroxide, tetraethylammonium hydroxide, choline, pyrrole, piperidine, or 1,8-diazabicyclo-[5,4,0]-7-undecene. The concentration of the developing solution is generally 0.001 wt % to 10 wt %, preferably 0.005 wt % to 5 wt %, and more preferably 0.01 wt % to 1 wt %.

After the pre-baked coating film is developed, the substrate having a specific pattern is rinsed with water, and then the specific pattern is air dried with compressed air or compressed nitrogen. Then, a post-bake treatment is conducted with a heating device such as a hot plate or an oven, and a black matrix can be formed on the substrate. The post-bake temperature is generally 150 to 250° C., wherein the heating time when using the hot plate is 5 minutes to 60 minutes and the heating time when using the oven is 15 minutes to 150 minutes.

### Preparation Method of Color Filter

The color filter of the present invention is fabricated by, firstly, uniformly applying (e.g., spin coating, casting coating, roll coating, etc.) a photosensitive resin composition for color filter on the substrate having the black matrix described above so as to form a coating film.

After the coating layer is formed, most of the solvent is removed by drying under reduced pressure. Next, the remaining solvent is completely removed by a pre-bake method to form a pre-baked coating film. The conditions for drying under reduced pressure and pre-baking can vary according to the components and the ratio of each component. Generally, the drying under reduced pressure is conducted at a pressure of 0 mmHg to 200 mmHg for 1 second to 60 seconds, and the pre-bake is a heat treatment conducted on the coating film at a temperature of 70° C. to 110° C. for 1 minute to 15 minutes.

Then, the pre-baked coating film is exposed with a photomask having a specific pattern. The light used in the exposure process is preferably an ultraviolet light such as a g-line, an h-line, or an i-line. In addition, the UV light irradiation device can be a(n) (ultra-)high pressure mercury vapor lamp or a metal halide lamp.

Then, the exposed pre-baked coating film is immersed in a developing solution at a temperature of 23±2° C. to remove the unexposed portion of the pre-baked coating film and to form a specific pattern on the substrate.

After the pre-baked coating film is developed, the substrate having a specific pattern is rinsed with water, and then the specific pattern is air dried with compressed air or compressed nitrogen. Then, a post-bake treatment is conducted with a heating device such as a hot plate or an oven. The conditions for the post-bake treatment are as described and are not repeated herein. The steps are repeated to form the pixel color layers of, for instance, red, green, and blue on the substrate.

Next, in a vacuum environment with a temperature of 220° C. to 250° C., an ITO protective film (deposited film) is formed on the surface of the pixel color layer by sputtering. The ITO protective film is etched and wired if necessary, and a liquid crystal alignment film (polyimide) is coated on the surface of the ITO protective film to form a color filter having a pixel layer.

Preparation of Liquid Crystal Display Device

The color filter as fabricated and a substrate with a thin film transistor (TFT) disposed thereon is oppositely disposed, and then a gap (cell gap) is disposed therebetween. Next, the surrounding area of the color filter and the substrate is adhered with an adhesive and an injection hole is left. Then, liquid crystal is injected through the injection hole into the gap separated by the substrate surface and the adhesive, and the injection hole is sealed to form a liquid crystal layer. Then, the liquid crystal display is fabricated by providing a polarizer to each of the side of the color filter not contacting the liquid crystal layer and the side of the substrate not contacting the liquid crystal layer.

The liquid crystal used, i.e., a liquid crystal compound or a liquid crystal composition, is not particularly limited. Any liquid crystal compound or liquid crystal composition can be used.

Moreover, the liquid crystal alignment film used in the color filter is used to limit the alignment of the liquid crystal molecules and is not particularly limited. Both inorganic matter and organic matter are allowed, and the invention is not limited thereto.

A plurality of embodiments are listed below to explain the application of the present invention. However, the embodiments are not used to limit the invention. Those having ordinary skill in the art can make various modifications and variations without departing from the scope and spirit of the invention.

### DETAILED DESCRIPTION

### Synthesis of the Alkali-Soluble Resin (A) Synthesis Example A-1-1

Firstly, 100 parts by weight of a fluorene epoxy compound (number ESF-300, made by Nippon Steel Chemical Co., Ltd., epoxy equivalent 231), 30 parts by weight of acrylic acid, 0.3 parts by weight of benzyltriethylammonium chloride, 0.1 parts by weight of 2,6-di-t-butyl-p-cresol, and 130 parts by weight of propylene glycol monomethyl ether acetate were added in a 500 ml four-neck flask in a continuous manner. The feeding speed was controlled at 25 parts by weight per minute, the temperature of the reaction process is maintained at 100° C. to 110° C., and the mixture was reacted for 15 hours to obtain a light yellow mixture solution having a solid component concentration of 50 wt %.

Then, 100 parts by weight of the as-prepared light yellow mixture is dissolved in 25 parts by weight of ethylene glycol monoethyl ether acetate, and 6 parts by weight of tetrahydrophthalic anhydride and 13 parts by weight of benzophenone tetracarboxylic dianhydride were added at the same time. Next, the mixture was heated to 110° C. to 115° C. and reacted for 2 hours to obtain the resin having an unsaturated group (A-1-1), of which an acid value is 98.0 mgKOH/g.

### Synthesis Example A-1-2

Firstly, 100 parts by weight of a fluorene epoxy compound (model number ESF-300, made by Nippon Steel Chemical Co., Ltd., epoxy equivalent 231), 30 parts by weight of acrylic acid, 0.3 parts by weight of benzyltriethylammonium chloride, 0.1 parts by weight of 2,6-di-t-butyl-p-cresol, and 130 parts by weight of propylene glycol monomethyl ether acetate were added in a 500 ml four-neck flask in a continuous manner. The feeding speed was controlled at 25 parts by weight/minute, the temperature of the reaction process is maintained at 100° C. to 110° C., and the mixture was reacted for 15 hours to obtain a light yellow mixture solution having a solid component concentration of 50 wt %.

Then, 100 parts by weight of the as-prepared light yellow mixture was dissolved in 25 parts by weight of ethylene glycol monoethyl ether acetate, and then 13 parts by weight of benzophenone tetracarboxylic dianhydride was added. Next, the mixture was reacted at 110° C. to 115° C. for 2 hours. Then, 6 parts by weight of tetrahydrophthalic anhydride was added, and the mixture was reacted at 90° C. to 95° C. for 4 hours to obtain the resin having an unsaturated group (A-1-2) of which an acid value was 99.0 mgKOH/g.

### Synthesis Example A-1-3

Firstly, 400 parts by weight of an epoxy compound (model number NC-3000, made by Nippon Kayaku Co., Ltd., epoxy equivalent 288), 102 parts by weight of acrylic acid, 0.3 parts by weight of methoxyphenol, 5 parts by weight of triphenylphosphine, and 264 parts by weight of propylene glycol monomethyl ether acetate were placed in a reaction flask. The temperature of the reaction process was maintained at 95° C. and the mixture was reacted for 9 hours to obtain an intermediate product having an acid value of 2.2 mgKOH/g. Then, 151 parts by weight of tetrahydrophthalic anhydride was added. Next, the mixture was reacted at 95° C. for 4 hours to obtain the resin having an unsaturated group (A-1-3) of which an acid value was 102 mgKOH/g and a weight average molecular weight was 3,200.

### Synthesis Example A-2-1

Firstly, 1 part by weight of 2,2′-azobisisobutyronitrile, 240 parts by weight of propylene glycol monomethyl ether acetate, 20 parts by weight of methacrylic acid, 15 parts by weight of styrene, 35 parts by weight of benzyl methacrylate, 10 parts by weight of glycerol monomethacrylate, and 20 parts by weight of N-phenylmaleimide were placed in a round-bottom flask provided with a stirrer. Then, a condenser was provided on the round-bottom flask and the round-bottom flask was filled with nitrogen gas. Next, the components were slowly stirred and the temperature was raised to 80° C. such that the reactants were uniformly mixed, and then a polymerization reaction proceeded for 4 hours. Then, the temperature was further raised to 100° C. and 0.5 parts by weight of 2,2′-azobisisobutyronitrile was added. After polymerizing for 1 hour, the another alkali-soluble resin (A-2-1) was obtained.

### Synthesis Example A-2-2

Firstly, 2 parts by weight of 2,2′-azobisisobutyronitrile, 300 parts by weight of di(propylene glycol)monomethyl ether, 15 parts by weight of methacrylic acid, 15 parts by weight of 2-hydroxyethyl acrylate, and 70 parts by weight of benzyl methacrylate were placed in a round-bottom flask provided with a stirrer. Then, a condenser was provided on the round-bottom flask and the round-bottom flask was filled with nitrogen gas. Next, the components were slowly stirred and the temperature was raised to 80° C. such that the reactants were uniformly mixed, and then a polymerization reaction proceeded for 3 hours. Then, the temperature was further raised to 100° C. and 0.5 parts by weight of 2,2′-azobisisobutyronitrile was added. Next, after polymerizing for 1 hour, the another alkali-soluble resins A-2-2 was obtained.

### Preparation of Photosensitive Resin Composition

The photosensitive resin compositions of Examples 1 to 7 and comparative examples 1 to 3 were prepared according to Tables 1 and 2 below.

### Example 1

100 parts by weight of the as-prepared alkali-soluble resin (A-1-1), 20 parts by weight of trimethylolpropane triacrylate (hereinafter abbreviated as B-1), 10 parts by weight of 1-[9-ethyl-6-(2-methylbenzoyl)-9H-carbazol-3-yl]-ethanone 1-(O-acetyloxime) (OXE-02 from Ciba, C-1 hereinafter), 60 parts by weight of MA100 (Product of Mitsubishi Chemical Corporation, E-1 hereinafter) and 2 parts by weight of 4,4′-bis[(4,6-dianilino-1,3,5-triazin-2-yl)amino]stilbene-2,2′-disulfonic sodium (hereinafter abbreviated as F-1) were added into 400 parts by weight of propylene glycol monomethyl ether acetate (hereinafter abbreviated as D-1) and uniformly mixed in a shaking type stirrer to form the photosensitive resin composition for black matrix of Example 1. The resulted photosensitive resin composition was evaluated in terms of heat-enduring resistance stability by the approach described below. The results were shown in Table 1.

### Examples 2 to 7 and Comparative Examples 1 to 3

The photosensitive resin compositions of examples 2 to 7 and comparative examples 1 to 3 were prepared by the same method as described in connection to example 1, except that the components and the amount of each component in the photosensitive resin composition were changed. The formula and the results of the evaluation are shown in Tables 1 and 2, and the details are omitted here.

### Evaluation Approach

### Heat-Enduring Resistance Stability

The photosensitive resin compositions of examples 1 to 7 and comparative examples 1 to 3 were fabricated into black matrices by the above-described method. Then, three points were randomly selected on the black matrix of each examples and each comparative examples, and at those points the surface resistance were measured by a high resistivity meter (MCP-HT450, Hiresta-UP from Mitsubishi Chemical), and the average value (Ωᵢ) of the surface resistance were calculated.

Then, the black matrix were placed in an oven at 300° C. After 80 minutes, the average value (Ω_{f}) of the surface resistivity of each of the black matrices were calculated by the same method as described above. The heat-enduring resistance stability ratio (R_{H}) of the black matrix were calculated by the following formula and evaluated by the following standards:

heat-enduring resistance stability (R_{H})=Ω_{f}/Ωᵢ*100% (III)

◯: 96%; R_{H}

Δ: 90%<R_{H}<96%

X: R_{H}≦90%

As shown in the results of Tables 1 and 2, when the alkali-soluble resin (A) includes resin having an unsaturated group (A-1) (A-1), the resulted photosensitive resin composition had a good heat-enduring resistance stability.

Moreover, when the photosensitive resin composition of the present invention included the fluorescent brightening agent (F), the resulted photosensitive resin composition had a good heat-enduring resistance stability.

It should be supplemented that, although specific compounds, components, specific reaction conditions, specific processes, specific evaluation methods or specific instruments are employed as exemplary embodiments of the present invention, for illustrating the photosensitive resin composition for black matrix and the application thereof. However, as is understood by a person skilled in the art instead of limiting to the aforementioned examples, the photosensitive resin composition for black matrix and the application of the same of the present invention also can be manufactured by using other compounds, components, reaction conditions, processes, evaluation methods and instruments without departing from the spirit and the scope of the present invention.

As is understood by a person skilled in the art, the foregoing embodiments of the present invention are illustrative rather than limiting of the present invention. In view of the foregoing, it is intended to cover various modifications and similar arrangements included within the spirit and the scope of the appended claims. Therefore, the scope of which should be accorded the broadest interpretation so as to encompass all such modifications and similar structures.

TABLE 1

| | | | Examples | | | | | | |
|---|---|---|---|---|---|---|---|---|---|
| Components | | | 1 | 2 | 3 | 4 | 5 | 6 | 7 |
| Alkali-soluble resin (A) | A-1 | A-1-1 | 100 | | | 100 | | | 30 |
| (parts by weight) | | A-1-2 | | 100 | | | 70 | | |
| | | A-1-3 | | | 100 | | | 50 | |
| | A-2 | A-2-1 | | | | | 30 | | 70 |
| | | A-2-2 | | | | | | 50 | |

| | | | | | | | | |
|---|---|---|---|---|---|---|---|---|
| Compound (B) having | B-1 | 20 | 40 | | | | | |
| an ethylenically | B-2 | | 40 | | 40 | | 140 | |
| unsaturated group | B-3 | | | 60 | | 120 | | 160 |
| (parts by weight) | | | | | | | | |
| Photoinitiator (C) | C-1 | 10 | | | 40 | 15 | 45 | |
| (parts by weight) | C-2 | | 15 | 30 | | | | 30 |
| | C-3 | | | | | 5 | | 30 |
| Solvent (D) | D-1 | 400 | 550 | 650 | | 2500 | 650 | |
| (parts by weight) | D-2 | | 250 | 650 | 2000 | | 2350 | 4000 |
| Pigment (E) | E-1 | 60 | | 200 | 150 | 400 | | 600 |
| (parts by weight) | E-2 | | 150 | | 150 | | 550 | |
| Fluorescent Brightening | F-1 | 2 | | | | | | 3 |
| Agent (F) | F-2 | | 0.1 | | | | | |
| (parts by weight) | F-3 | | | 0.5 | | | | |
| | F-4 | | | | 1 | | | |
| | F-5 | | | | | 0.8 | | 2 |
| | F-6 | | | | | | 3 | |
| Additive (G) | G-1 | | | | 2 | | | |
| (parts by weight) | G-2 | | 1 | | | | | |
| evaluation results | heat-enduring | ∘ | ∘ | ∘ | ∘ | ∘ | ∘ | ∘ |
| | resistance | | | | | | | |

B-1 trimethylolpropane triacrylate
B-2 dipentaerythritol tetracrylate
B-3 dipentaerythritol hexacrylate
C-1 1-[9-ethyl-6-(2-methylbenzoyl)-9H-carbazol-3-yl]-ethanone 1-(O-acetyloxime) (product name: OXE-02, made by Ciba Specialty Chemicals Co., Ltd.)
C-2 1-[4-(phenylthio)phenyl]-octane-1,2-dione 2-(O-benzoydoxime) (product name: OXE-01, made by Ciba Specialty Chemicals Co., Ltd.)
C-3 2-methyl-1-[4-(methylthio)phenyl]-2-morpholino-1-propanone (product name: IRGACURE 907, made by Ciba Specialty Chemicals Co., Ltd.)
D-1 propylene glycol monomethyl ether acetate
D-2 ethyl 3-ethoxy propionate
E-1 MA100 (made by Mitsubishi Chemical Corporation)
E-2 MA230 (made by Mitsubishi Chemical Corporation)
F-1 4,4′-bis [(4,6-dianilino-1,3,5-triazin-2-yl)amino] stilbene-2,2′-disulfonic sodium
F-2 4,4′-bis[(4-anilino-6-(2-hydroxyethyl)methylamino-1,3,5-triazin-2-yl)amino] stilbene-2,2′-disulfonic sodium
F-3 Diethylaminomethyl coumarin
F-4 4-methyl-7-diethylcoumarin
F-5 2,5-thiophenediylbis(5-tert-butyl-1,3-benzoxazole)
F-6 benzoxazole-2,2′-(2,5-thiophenediyl)-bis[5-(1,1-dimethylethyl)]
G-1 SF-8427 (made by Foray Dow Corning Silicon)
G-2 KBM-403 (made by Shin-Etsu)

TABLE 2

| | | | Comparative examples | | |
|---|---|---|---|---|---|
| Components | | | 1 | 2 | 3 |
| Alkali-soluble resin (A) | A-1 | A-1-1 | | 100 | |
| (parts by weight) | | A-1-2 | | | |
| | | A-1-3 | | | |
| | A-2 | A-2-1 | 100 | | |
| | | A-2-2 | | | 100 |

| | | | | |
|---|---|---|---|---|
| Compound (B) having an | B-1 | 100 | | |
| ethylenically unsaturated group | B-2 | | 80 | |
| (parts by weight) | B-3 | | | 60 |
| Photoinitiator (C) | C-1 | 10 | | |
| (parts by weight) | C-2 | | 15 | 30 |
| | C-3 | | | |
| Solvent (D) | D-1 | 1000 | | |
| (parts by weight) | D-2 | | 2000 | 2000 |
| Pigment (E) | E-1 | 350 | | 200 |
| (parts by weight) | E-2 | | 300 | |
| Fluorescent Brightening Agent | F-1 | 2 | | |
| (F) (parts by weight) | F-2 | | | |
| | F-3 | | | |
| | F-4 | | | |
| | F-5 | | | |
| | F-6 | | | |
| Additive (G) | G-1 | | | |
| (parts by weight) | G-2 | | | |
| evaluation results | heat-enduring | X | X | X |
| | resistance | | | |

B-1 trimethylolpropane triacrylate
B-2 dipentaerythritol tetracrylate
B-3 dipentaerythritol hexacrylale
C-1 1-[9-ethyl-6-(2-methylbenzoyl)-9H-carbazol-3-yl]-ethanone 1-(O-acetyloxime) (product name: OXE-02, made by Ciba Specialty Chemicals Co., Ltd.)
C-2 1-[4-(phenylthio)phenyl]-octane-1,2-dione 2-(O-benzoyloxime) (product name: OXE-01, made by Ciba Specialty Chemicals Co., Ltd.)
C-3 2-methyl-1-[4-(methylthio)phenyl]-2-morpholino-1-propanone (product name: IRGACURE 907, made by Ciba Specialty Chemicals Co., Ltd.)
D-1 propylene glycol monomethyl ether acetate
D-2 ethyl 3-ethoxy propionate
E-1 MA100 (made by Mitsubishi Chemical Corporation)
E-2 MA230 (made by Mitsubishi Chemical Corporation)
F-1 4,4′-bis[(4,6-dianilino)-1,3,5-triazin-2-yl)amino]stilbene-2,2′-disulfonic sodium
F-2 4,4′-bis[(4-anilino-6-(2-hydroxyethyl)methylamino-1,3,5-triazin-2-yl)amino] stilbene-2,2′-disulfonic sodium
F-3 Diethylaminomethyl coumarin
F-4 4-methyl-7-diethylcoumarin
F-5 2,5-thiophenediylbis(5-tert-butyl-1,3-benzoxazole)
F-6 benzoxazole-2,2′-(2,5-thiophenediyl)-bis[5-(1,1-dimethylethyl)]
G-1 SF-8427 (made by Toray Dow Corning Silicon)
G-2 KBM-403 (made by Shin-Etsu)

What is claimed is:

1. A photosensitive resin composition for black matrix, comprising:
an alkali-soluble resin (A) comprising a resin having an unsaturated group (A-1), wherein the resin having an unsaturated group (A-1) is obtained by polymerizing a mixture, and the mixture comprises an epoxy compound having at least two epoxy groups (a-1-1) and a compound having at least one carboxylic group and at least one ethylenically unsaturated group (a-1-2);
a compound having an ethylenically unsaturated group (B);
a photoinitiator (C);
a solvent (D);
a black pigment (E); and
a fluorescent brightening agent (F), wherein the fluorescent brightening agent (F) is selected from at least one of stilbene derivatives, coumarin derivatives and benzoxazole derivatives.

2. The photosensitive resin composition for black matrix of claim 1, wherein the epoxy compound having at least two epoxy groups (a-1-1) comprises a compound having a structure shown in formula (I), a compound having a structure shown in formula (II) or a combination thereof: 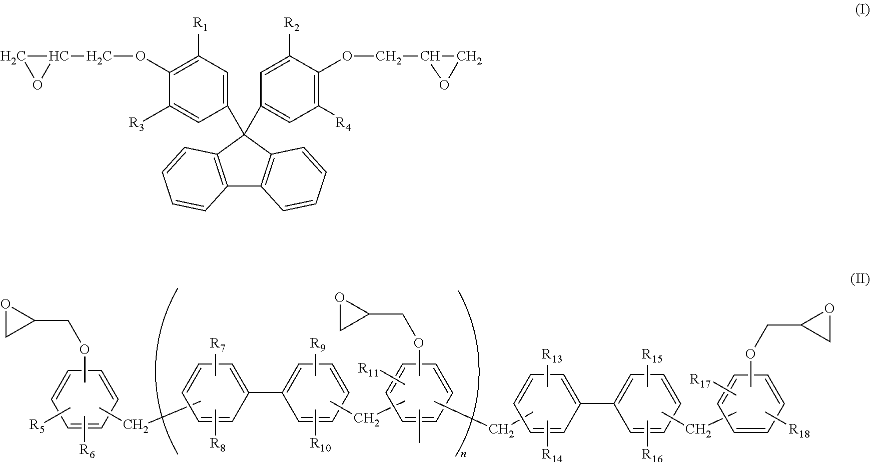
in the formulae (I) and (II), the R₁ to the R₄ each independently represent a hydrogen atom, a halogen atom, a C₁-C₅ alkyl group, a C₁-C₅ alkoxy group, a C₆-C₁₂ aryl group or a C₆-C₁₂ aralkyl group; the R₅ to the R₁₈ each independently represent a hydrogen atom, a halogen atom, a C₁-C₈ alkyl group or a C₆-C₁₅ aryl group; and the n represents an integer of 0 to 10.

3. The photosensitive resin composition for black matrix of claim 1, wherein based on a usage amount of 100 parts by weight of the alkali-soluble resin (A), a usage amount of the resin having an unsaturated group (A-1) is 30 parts by weight to 100 parts by weight, a usage amount of the compound having an ethylenically unsaturated group (B) is 20 parts by weight to 160 parts by weight, a usage amount of the photoinitiator (C) is 10 parts by weight to 60 parts by weight, a usage amount of the solvent (D) is 400 parts by weight to 4000 parts by weight, a usage amount of the black pigment (E) is 60 parts by weight to 600 parts by weight, and a usage amount of the fluorescent brightening agent (F) is 0.1 parts by weight to 5 parts by weight.

4. A black matrix formed by pre-baking, exposuring, developing, and post-baking a photosensitive resin composition for black matrix, wherein the photosensitive resin composition for black matrix comprises:
an alkali-soluble resin (A) comprising a resin having an unsaturated group (A-1), wherein the resin having an unsaturated group (A-1) is obtained by polymerizing a mixture, and the mixture comprises an epoxy compound having at least two epoxy groups (a-1-1) and a compound having at least one carboxylic group and at least one ethylenically unsaturated group (a-1-2);
a compound having an ethylenically unsaturated group (B);
a photoinitiator (C);
a solvent (D);
a black pigment (E); and
a fluorescent brightening agent (F), wherein the fluorescent brightening agent (F) is selected from at least one of stilbene derivatives, coumarin derivatives and benzoxazole derivatives.

5. The black matrix of claim 4, wherein the epoxy compound having at least two epoxy groups (a-1-1) comprises a compound having a structure shown in formula (I), a compound having a structure shown in formula (II) or a combination thereof: 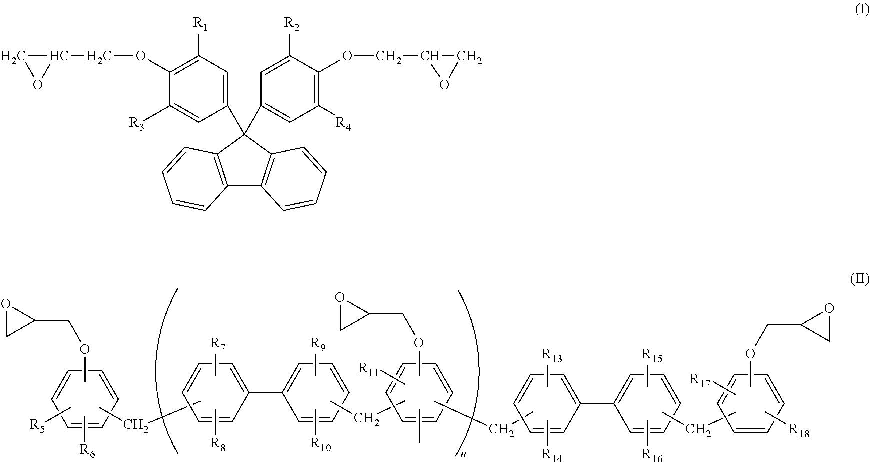
in the formulae (I) and (II), the R₁ to the R₄ each independently represent a hydrogen atom, a halogen atom, a C₁-C₅ alkyl group, a C₁-C₅ alkoxy group, a C₆-C₁₂ aryl group or a C₆-C₁₂ aralkyl group; the R₅ to the R₁₈ each independently represent a hydrogen atom, a halogen atom, a C₁-C₈ alkyl group or a C₆-C₁₅ aryl group; and the n represents an integer of 0 to 10.

6. The black matrix of claim 4, wherein, based on a usage amount of 100 parts by weight of the alkali-soluble resin (A), a usage amount of the resin having an unsaturated group (A-1) is 30 parts by weight to 100 parts by weight, a usage amount of the compound having an ethylenically unsaturated group (B) is 20 parts by weight to 160 parts by weight, a usage amount of the photoinitiator (C) is 10 parts by weight to 60 parts by weight, a usage amount of the solvent (D) is 400 parts by weight to 4000 parts by weight, a usage amount of the black pigment (E) is 60 parts by weight to 600 parts by weight, and a usage amount of the fluorescent brightening agent (F) is 0.1 parts by weight to 5 parts by weight.

7. A color filter comprising the black matrix of claim 4.

8. A liquid crystal display comprising the color filter of claim 7.
